(19) United States
(12) Patent Application Publication
(10) Pub. No.: US 2006/0291165 A1
(43) Pub. Date: Dec. 28, 2006

(54) Apparatus for cooling electronic components

(75) Inventors: Markus Flesch, Kornwestheim (DE); Thomas Siebrecht, Ludwigsburg (DE)

Correspondence Address: FOLEY AND LARDNER LLP;SUITE 500, 3000 K STREET NW, WASHINGTON, DC, 20007, US

(73) Assignee: BEHR INDUSTRY GmbH & CO. KG

(21) Appl. No.: 11/443,477

(22) Filed: May 31, 2006

(30) Foreign Application Priority Data
May 31, 2005 (DE) 10 2005 025 381.4

(51) Int. Cl. H05K 7/20

(52) U.S. Cl. 361/699

(57) ABSTRACT

An apparatus (1) for cooling electronic components comprises plate-shaped elements (2, 8), which enclose between them a cavity in the form of a flow channel, having connections (5, 6) for a liquid coolant flowing through the flow channel. One plate-shaped element comprises a highly thermally conductive, preferably metallic plate (8) connected in a thermally conductive manner to the electronic components. The flow channel can be matched, in terms of its arrangement and/or design, in particular as regards its flow length between the coolant connections (5, 6) and as regards its flow cross section, to provide selective location of higher cooling capacity for points having a high degree of heat development from the electronic components

### CROSS-REFERENCE TO RELATED PATENT APPLICATIONS

The right of foreign priority is claimed under 35 U.S.C. § 119(a) based on Federal Republic of Germany Application No. 10 2005 025 381.4, filed May 31, 2005, the entire contents of which, including the specification, drawings, claims and abstract, are incorporated herein by reference.

### BACKGROUND OF THE INVENTION

The present invention relates generally to an apparatus for cooling electronic components, and more particularly to such an apparatus that includes plural mating plate-shaped elements that form a housing which encloses between them a cavity forming a flow channel. The housing has inlet and outlet connections communicating with the cavity for a liquid coolant flowing through the flow channel, and one of the plate-shaped elements comprises a highly thermally conductive plate that is connected in a thermally conductive manner to the electronic components which produce an inhomogeneous pattern of heat development.

Various types of cooling apparatus for electronic components are known in various designs, in which cases the cooling takes place either by means of ambient air or by means of a liquid coolant. EP 0 278 240 A2 discloses a heat sink having a thermally conductive, metallic base plate, on which a cooling element in the form of a stack of fins or ribs is fixed by means of brazing. This cooling element is cooled by an ambient air stream. In this case, the thermally conductive base plate is in thermally conductive contact with the electronic components. DE 198 06 978 A1 discloses an apparatus for cooling electronic components by means of convection, in which case a cooling air stream is passed through channels equipped with fins of a heat sink, for heat dissipation purposes. The heat sink is connected in a thermally conductive manner to the electronic components.

Commonly assigned DE 41 31 739 A1 discloses a cooling device for electrical components, in which case two plate-shaped components, a thermally conductive base plate and a cover plate, are connected to one another and enclose a cavity, through which a liquid coolant flows. In order to increase the heat transfer, an insert for the purpose of generating turbulence is arranged in the cavity and is preferably brazed to the base plate. Effective heat dissipation of the power loss generated by the electrical components is therefore achieved.

DE 199 11 205 A1 discloses a similar liquid-cooled apparatus for electronic components, in which case a base plate is produced from a metallic material and a cover plate is produced from a plastic. The base plate and cover plate enclose between them a cavity which is in the form of a flow channel and includes a internal cooling fin (a so-called turbulence insert). The liquid coolant flows through said cavity. In one preferred embodiment, the coolant connections are arranged on the same side, which results in the coolant being deflected in the cavity. One disadvantage with the known cooling apparatuses, even the liquid-cooled apparatuses, is the relatively large amount of physical space that is required for the dissipation of the heat due to relatively large power losses - as occur, for example, in the case of motor vehicle electronics.

### SUMMARY OF THE INVENTION

One object of the present invention is to provide an improved apparatus for cooling electronic components in terms of its efficiency and also in terms of reducing the amount of physical space it requires.

According to one aspect of the present invention, there is provided an apparatus for cooling electronic components, comprising: plural mating plate-shaped elements, which form a housing that encloses between them a cavity forming a flow channel, the housing having inlet and outlet connections communicating with the cavity for a liquid coolant flowing through the flow channel. One of the plate-shaped elements comprises a highly thermally conductive plate that is connected in a thermally conductive manner to the electronic components which produce an inhomogeneous pattern of heat development, wherein the flow channel comprises at least one structural element that selectively matches flow cross section of the fluid flow channel, in terms of its arrangement and design, to the location of points having a high degree of heat development owing to the electronic components.

In accordance with another aspect of the invention, there is provided a motor vehicle comprising an internal combustion engine and an engine control system for the engine, wherein said engine control system is contained as the electronic component in a cooling apparatus as defined above.

These and further objects, features and advantages of the present invention will become apparent from the detailed description of preferred embodiments that follows, when considered together with the accompanying figures of drawing.

### BRIEF DESCRIPTION OF THE DRAWINGS

In the drawings:

FIG. 1 is a perspective plan view showing a cooling apparatus as viewed looking at the base;

FIG. 1a is a further perspective view showing the cooling apparatus of FIG. 1 from the side of the cover plate;

FIG. 1b is a top perspective view showing the cooling apparatus of FIG. 1 without a cover plate; and

FIG. 2 is an exploded view showing the various parts of the cooling apparatus shown in FIG. 1.

### DETAILED DESCRIPTION OF THE PREFERRED EMBODIMENTS

The invention provides for the flow channel, through which the coolant can flow, to be matched to the locally different conditions as regards the heat to be dissipated, such that an approximately uniform temperature distribution results on the entire contact area between the electronics and the cooling plate. The invention is based on the observation that the heat input from a unit of electronic components, e.g., a so-called printed circuit board, is inhomogeneous in relation to the surface of the printed circuit board, which is in thermally conductive contact with the cooling plate or cover plate of the cooling apparatus. This is due to the different power loss of the individual modules. On the other hand, in the prior art, the heat dissipation by means of a coolant which flows over the cooling plate is relatively uniform, with the result that particularly hot points, so-called hot spots, are formed.

The invention now provides for the heat transfer conditions to be matched variably and selectively, i.e., to the specific conditions of the electronic module, owing to an appropriate design and arrangement of the flow channel, for example, as regards its flow length and its flow cross section. It is thus possible, for example, by means of constricting the flow channel in the region of a hot spot, to locally and selectively achieve an increased flow rate of the coolant there and thus improved heat dissipation. The temperature variations are thereby leveled. On the other hand, by means of targeted deflections of the flow channel, it is possible for the coolant to be passed to the hot spots, i.e., to the regions with a relatively high heat output. With this targeted heat dissipation, it is possible to achieve greater cooling performance given a small amount of physical space.

Advantageous preferred refinements of the invention are also described herein. The flow path (or the flow length), i.e., the extent or distance covered by the flow medium between the inlet and outlet in the cooling apparatus, can advantageously be increased by one or more deflections. This not only increases the cooling performance, but also the coolant is passed in a targeted manner to preferred points with a high heat output on the part of the electronics. Effective heat dissipation and homogenization of the temperature distribution are thus achieved.

The deflections of the coolant are advantageously achieved by means of webs which force, for example, a meandering course of the coolant through the cooling apparatus. In one advantageous preferred embodiment, the webs can be formed into and/or onto a plate of the cooling apparatus, a so-called base, i.e., they can be formed integrally therewith. In this case, the base is preferably produced from an aluminum sheet using a progressive die or follow-on die, and the inlet and outlet channels for the coolant are also preferably formed at the same time.

In order to increase the heat transfer to the coolant side, so-called turbulence inserts are provided which are of conventional design and can be brazed both to the base and/or to the cover plate of the cooling apparatus. This results in a compact, highly thermally conductive cooling apparatus which is resistant to internal pressure. Production is extremely simple and therefore inexpensive, since the base and the cover plate can be produced by conventional techniques from sheet metal parts, for example, an aluminum sheet. This can be done, for example, by means of non-cutting processing (stamping and embossing) using a tool, e.g., a so-called progressive die or follow-on die.

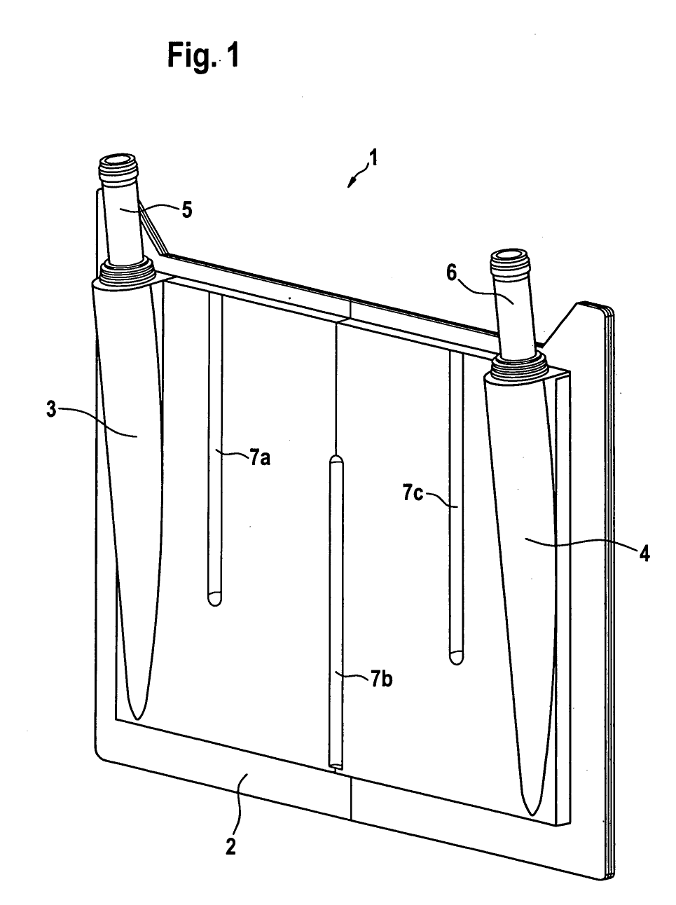

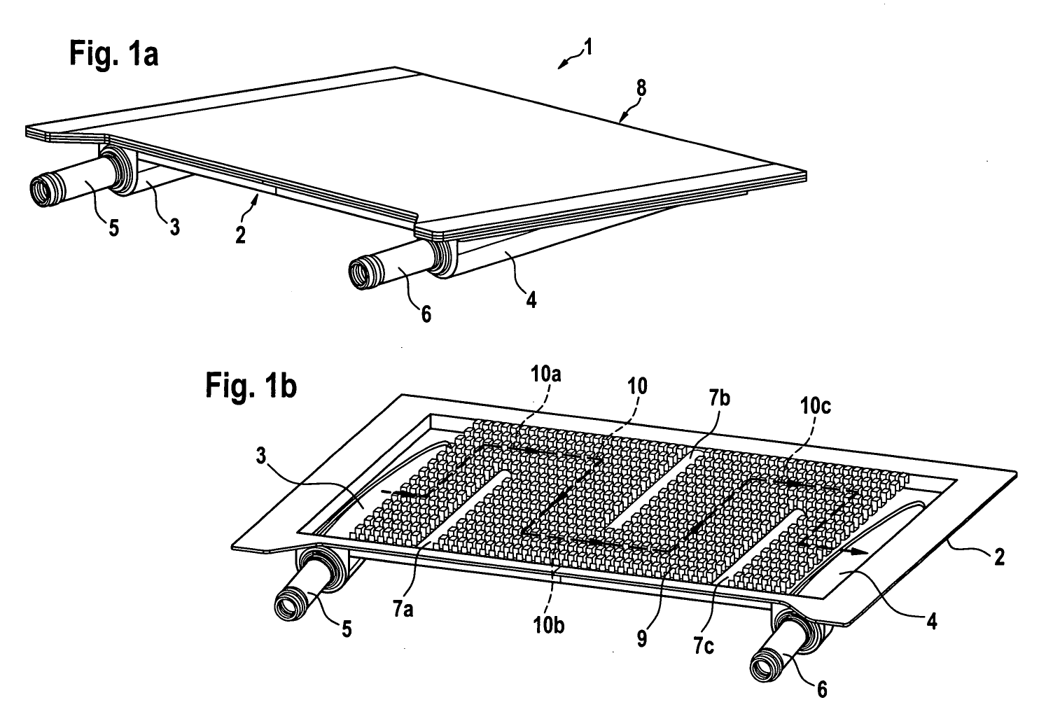

Turning now to the drawings, FIG. 1 shows a cooling apparatus 1 for cooling electronic components (not illustrated specifically), preferably of an electronic engine management system for a motor vehicle. The cooling apparatus 1 has a base 2, from which an inlet channel 3 and an outlet channel 4 for a liquid coolant are formed. An inlet connector 5 is plugged into the inlet channel 3, and an outlet connector 6 is plugged into the outlet channel 4, and said inlet connector 5 and outlet connector 6 are brazed tightly to the base 2. In addition, separating or diverting webs 7a, 7b, 7c are formed in the base 2 and extend with their embossed section to the inside of the cooling apparatus.

FIG. 1a shows the cooling apparatus 1 in a different view, that is to say with a view of a cover plate 8, which is located on the side opposite the base 2 and is connected, preferably brazed, at the edge to the base 2. The base 2 with its inlet and outlet channels 3, 4 is therefore located on the underside in this illustration. The cover plate 8 is essentially smooth and flat and, as cannot be seen here, is in thermally conductive contact with a printed circuit board on which electronic modules are fixed. The printed circuit board (not illustrated in detail) with the electronic modules rests flat on the cover plate 8 and is preferably adhesively bonded to it by means of a thermally conductive adhesive. The printed circuit board and the cooling apparatus 1 therefore form a structural unit, which can be fitted as such, for example, as an engine management system which is to be cooled in a motor vehicle.

FIG. 1b shows the cooling apparatus 1 without the cover plate 8, i.e., the cover plate 8 has been removed, and gives a free view into the interior of the cooling apparatus 1. It shows the separating webs 7a, 7b, 7c and the open inlet and outlet channels 3, 4. A so-called turbulence insert 9 is inserted between the channels 3, 4 and the separating webs 7a, 7b, 7c, with the turbulence insert 9 being cut out at the points of the separating webs 7a, 7b, 7c. The cooling apparatus 1 is preferably connected to the coolant circuit of an internal combustion engine (not illustrated) of the motor vehicle and has the coolant flowing through it. Owing to the separating webs 7a, 7b, 7c, the coolant flow is forced to have a meandering course—illustrated by a dashed arrow 10 with three deflections 10a, 10b, 10c.

In the illustrative representation, the separating webs 7a, 7b, 7c are arranged approximately at the same distances from one another and also have approximately the same length. However, this is only a preferred exemplary embodiment; the flow course can also be varied depending on the position of the electronic modules and depending on the level of their power loss, such that regions of flow acceleration and higher rates of flow result for the coolant stream, which result in increased heat dissipation. This can be achieved by constricting the flow cross section, whether it be by reducing the distance from the adjacent separating webs or by curving, extending or shortening the separating webs such that the flow cross section is different in the deflection regions 10a, 10b, 10c.

By selecting turbulence inserts with a higher or lower flow resistance, it is also possible to locally influence the heat transfer, or this can be done by having individual sections of the flow path that do not have any turbulence plates at all. Owing to these and other well understood measures, the heat transfer and thus the heat dissipation can be selectively locally varied and can be matched to the inhomogeneous heat output from the printed circuit board of the electronic components.

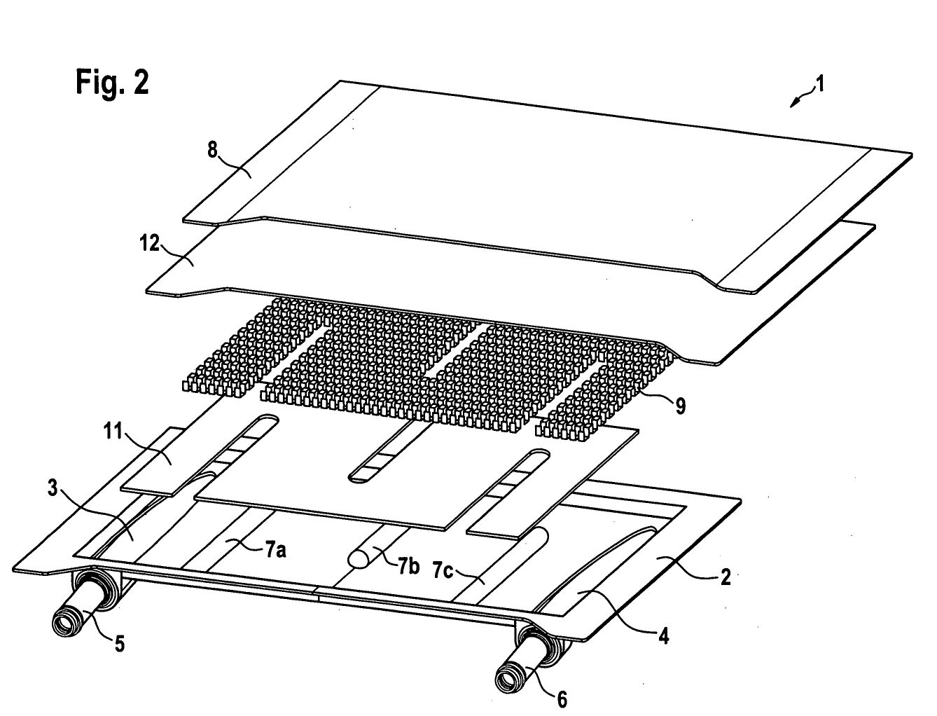

FIG. 2 shows the cooling apparatus 1 in an exploded illustration, the individual parts being illustrated spaced apart prior to assembly and in a parallel arrangement. The same reference numerals are used for identical components. A foil-shaped braze carrier (braze foil) 11 is illustrated between the base 2 and the turbulence sheet 9. The braze carrier 11 is cut out in the region of the separating webs 7a, 7b, 7c. A further braze carrier (braze foil) 12 is arranged between the cover plate 8 and the turbulence sheet 9. Once all of the parts (which are preferably produced from aluminum alloys) have been assembled, both braze foils 11, 12 bring about brazing of the base 2 and the cover plate 8 in a circumferential edge region and in the region of the separating webs 7a, 7b, 7c. The turbulence sheet 9 is likewise preferably brazed both to the cover plate 8 and to the base 2. This provides a cavity which is in the form of a meandering flow channel between the inlet channel and the outlet channel. As has already been mentioned, the flow channel is matched to the heat “topography” of the electronics printed circuit board and is therefore variable, in order to achieve optimum heat dissipation via the flowing coolant.

As has been mentioned above, a printed circuit board having electronic components is fixed in a thermally conductive manner, preferably adhesively bonded, to the smooth cover plate 8 so as to produce a structural unit which can be transported and can be easily fitted.

The foregoing description of preferred embodiments of the invention has been presented for purposes of illustration and description only. It is not intended to be exhaustive or to limit the invention to the precise form disclosed, and modifications and variations are possible and/or would be apparent in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto and that the claims encompass all embodiments of the invention, including the disclosed embodiments and their equivalents.

What is claimed is:

1. An apparatus for cooling electronic components, comprising:
plural mating plate-shaped elements, which form a housing that encloses between them a cavity forming a flow channel, the housing having inlet and outlet connections communicating with the cavity for a liquid coolant flowing through the flow channel, one of the plate-shaped elements comprising a highly thermally conductive plate that is connected in a thermally conductive manner to the electronic components which produce an inhomogeneous pattern of heat development, wherein the flow channel comprises at least one structural element that matches flow cross section of the fluid flow channel, in terms of its arrangement and/or design, to the location of points having a high degree of heat development owing to the electronic components.

2. The apparatus of claim 1, wherein the at least one structural element permits varying the flow length of the flow channel between the coolant inlet and outlet connections.

3. The apparatus of claim 1, wherein said highly thermally conductive plate comprises a metal.

4. The apparatus of claim 1, wherein the at least one element comprises at least one flow-diverting web that creates said flow channel having at least one deflection.

5. The apparatus of claim 4, wherein said at least one flow diverting web comprises three flow diverting webs, whereby the flow channel has three deflections.

6. The apparatus of claim 5, wherein the three flow diverting webs are fixed at two sides to two mating plate-shaped elements.

7. The apparatus of claim 1, wherein the inlet and outlet connections are located in one of said plate-shaped elements comprising a base sheet.

8. The apparatus of claim 7, wherein the base sheet comprises a deep-drawn part formed from an aluminum sheet.

9. The apparatus of claim 1, further comprising turbulence generators arranged between the mating plate-shaped elements in the region of the flow channel.

10. The apparatus of claim 9, wherein the plate-shaped elements and the turbulence generators are brazed to one another.

11. The apparatus of claim 1, wherein the cooling apparatus with the electronic components forms a single integral structural unit.

12. The apparatus of claim 1, wherein the electronic components comprise an engine control system for an internal engine of a vehicle.

13. A motor vehicle comprising an internal combustion engine and an engine control system for the engine, wherein said engine control system is contained as the electronic component in a cooling apparatus as defined in claim 1.
